(19) United States
(12) Patent Application Publication
(10) Pub. No.: US 2026/0204523 A1
(43) Pub. Date: Jul. 16, 2026

(54) METHOD AND DEVICE FOR PROVIDING A PLASMA FOR PLASMA TREATMENT

(71) Applicants: Gerhard EICHENHOFER, Holzgerlingen (DE); GRUENWALD LABORATORIES GMBH, Taxenbach (AT)

(72) Inventors: Johannes GRÜNWALD, Taxenbach (AT); Gerhard EICHENHOFER, Holzgerlingen (DE)

(21) Appl. No.: 19/133,624

(22) PCT Filed: Nov. 28, 2023
(86) PCT No.: PCT/AT2023/060416

§ 371 Date: May 28, 2025

(30) Foreign Application Priority Data
Nov. 28, 2022 (AT) A 50903/2022

(51) Int. Cl. H01J 37/32; C23C 16/50

(52) U.S. Cl. CPC H01J 37/32651; C23C 16/50; H01J 37/32422

(57) ABSTRACT

A method for providing a plasma for plasma treatment of a surface of a substrate, includes providing a process chamber with a substrate in the process chamber; and providing a shielding electrode grid in the process chamber so that a Faraday cage is formed around the substrate, or the part of the substrate to be processed. The shielding electrode grid is electrically conductive and is connected to ground or to a negative potential with respect to ground. providing a plasma in the process chamber. A voltage is applied to the substrate. The shielding electrode grid extends above the surface of the substrate to be plasma treated at a distance of less than or equal to 10 mean free paths of the ions in the plasma. A corresponding device performs a method for providing a plasma for plasma treatment of a surface of a substrate.

### CROSS-REFERENCE TO RELATED APPLICATION

The present application is a National Stage Application of PCT International Application No.: PCT/AT2023/060416 filed on Nov. 28, 2023, which claims priority to Austrian Patent Application A 50903/2022, filed on Nov. 28, 2022, the disclosure of which is incorporated herein by reference in its entirety.

### TECHNICAL FIELD

The invention relates to a method and a device for providing a plasma for plasma treatment of a surface of a substrate.

### PRIOR ART

Various plasma assisted methods for coating, surface modification, material removal or doping of a substrate are known. A number of methods are known in which the use of a grid is provided.

For example, US 2001/0046566 A1 relates to plasma immersion ion implantation (PIII). A conductive 2D grid is provided between a wafer and the plasma source. The grid thus separates the plasma from the workpiece. Plasma immersion ion implantation (PIII) is also described, for example, in Mantese, Joseph V., et al. “Plasma-immersion ion implantation.” Mrs Bulletin 21.8 (1996): 52-56. Disadvantageously, the plasma there forms in the entire vacuum chamber and must necessarily be operated in pulsed mode.

Another known method is active screen nitriding, see e.g. Li, C. X. “Active screen plasma nitriding—an overview.” Surface Engineering 26.1-2 (2010): 135-141. There, a pre-tensioned grid is used, which is also part of the plasma generation.

Inverted fireballs (IFB) methods are also known, see, for example, Stenzel, R. L., et al. “Transit time instabilities in an inverted fireball. I. Basic properties.” Physics of Plasmas 18.1 (2011): 012104. Here, too, a bias voltage is applied to a grid. Disadvantageously, this method cannot be used for PVD processes.

The above-mentioned methods disadvantageously do not achieve a homogeneous surface treatment, a large-area surface treatment, are not energy-efficient and/or do not allow precise control over the energy of the ions striking the substrate or over the layer thickness or penetration depth.

It is the object of the present invention to eliminate or alleviate at least one of the disadvantages of the prior art. In particular, it is an object of the invention to provide a plasma assisted method which allows homogeneous deposition or coating, nitriding, plasma etching, ion implantation and/or enrichment of dopants in the substrate; to provide a more energy-efficient method; to achieve a higher plasma concentration around the substrate, in particular in the region of a surface to be plasma treated; and/or to provide more precise control over the process of surface treatment.

This is achieved by a method for providing a plasma for plasma treatment of a surface of a substrate,
providing a process chamber;
providing a substrate in the process chamber;
providing a shielding electrode grid in the process chamber, wherein at least one region of the shielding electrode grid (5) extends at a distance from and along the surface (2) to be plasma treated, such that the shielding electrode grid (5) substantially covers the surface (2) to be plasma treated, wherein the shielding electrode grid is electrically conductive;
providing a plasma in the process chamber;
applying a voltage to the substrate;
wherein the region of the shielding electrode grid opposite the surface (2) to be plasma treated extends at a distance of less than or equal to 10 mean free paths for electron-neutral gas particle collisions of the plasma from the surface to be plasma treated.

This is further achieved by a device for providing a plasma for plasma treatment of a surface of a substrate, comprising:
a process chamber;
a substrate holder for holding the substrate in the process chamber;
a shielding electrode grid in the process chamber, wherein at least one region of the shielding electrode grid extends at a distance from and along the surface to be plasma treated (or substrate holder), such that the shielding electrode grid substantially covers the surface to be plasma treated (or substrate holder), wherein the shielding electrode grid is electrically conductive;
a plasma source for providing a plasma in the process chamber;
a voltage source for applying a voltage to a substrate held by the substrate holder;
wherein the region of the shielding electrode grid opposite the surface to be plasma treated extends at a distance of less than or equal to 20 cm from the surface to be plasma treated (or substrate holder).

The shielding electrode grid primarily shields alternating fields of the plasma source and enables the generation of a spatially narrow, homogeneous plasma with high plasma density between the shielding electrode grid and the surface to be plasma treated, which in turn enables high growth or etching rates of the layers to be applied/removed or rapid doping rates. Due to the narrow spatial limitation of the plasma in the space adjacent to the surface of the substrate to be treated, a considerable part of the process energy to be introduced is also saved, which significantly increases the energy efficiency. In addition, for some applications, the external plasma source can also be switched off (after some time).

Due to the shielding effect of the shielding electrode grid and its arrangement close to the surface to be plasma treated, a highly reactive plasma with little dead volume can be generated. As a result, energy coupling is maximised, resulting in highly efficient processes. The strong spatial limitation of the plasma means that excitation/ionization takes place for the most part in the process-relevant volume. The structure allows complete control over the energy of the ions that strike the substrate and thus tailor-made ion implantation, coatings, surface erosion (etching, cleaning), surface modification with ions and supplantation, etc. The layer thickness or penetration depth during nitration, oxidation or other doping or coating processes can be freely adjusted. The high plasma densities in the process-relevant volume allow significant energy savings compared to conventional processes. Compared to a distant, two-dimensional grid, which can only serve as a charge filter or shield, the shielding electrode grid provided close to the surface to be plasma treated (optionally together with the process chamber) preferably acts as a Faraday cage, which encloses the (dense) plasma around the substrate, in particular the surface to be plasma treated, and thus increases the plasma density. Adjacent to the shielding electrode grid, in particular within the Faraday cage, the substrate becomes an active electrode that attracts the plasma. Homogeneous coatings/surface modifications/material ablation/doping are also possible on surfaces whose extent is significantly above the mean free path in the plasma, as long as in at least one spatial direction the distance of the shielding electrode grid from the surface to be plasma treated is less than or equal to 10 mean free paths for electron-neutral gas particle collisions or less than or equal to 20 cm.

The shielding electrode grid is preferably provided in such a way that it forms a Faraday cage around the surface to be plasma treated. In particular, the Faraday cage can be formed by the shielding electrode grid alone or together with the process chamber. The shielding electrode grid may also be floating or biased. Preferably, a region of the shielding electrode grid extends substantially parallel to the surface to be plasma treated. The fact that the shielding electrode grid substantially covers the surface to be plasma treated is understood to mean that a normal projection (normal to at least a partial area of the surface) of the shielding electrode grid onto the surface to be plasma treated covers said surface. The substrate may also be a part of an overall substrate to be processed.

The shielding electrode grid runs at least partially opposite the surface of the substrate to be plasma treated at a distance of preferably less than or equal to 5, particularly preferably less than or equal to 2, mean free paths for electron-neutral gas particle collisions of the plasma. The region of the shielding electrode grid opposite the surface to be plasma treated has a normal distance from the surface to be plasma treated of the substrate to be held by the substrate holder of preferably less than or equal to 20 cm, particularly preferably less than or equal to 5 cm, even more preferably less than or equal to 0.5 cm. The Faraday cage has an extension of preferably less than 20 cm, particularly preferably less than 5 cm, even more preferably less than 0.5 cm, in a direction normal to the surface to be plasma treated of the substrate to be held by the substrate holder. In a direction normal to the surface of the substrate to be held by the substrate holder, the Faraday cage has an extension of preferably less than 10 mean free paths for electron-neutral gas particle collisions of the plasma, particularly preferably less than 5 mean free paths for electron-neutral gas particle collisions of the plasma, even more preferably less than 2 mean free paths for electron-neutral gas particle collisions of the plasma. The device is preferably configured to provide a plasma having a certain mean free path length for electron-neutral gas particle collisions. The device is preferably set up to carry out the method. The distance indications with respect to the surface to be plasma treated can preferably also be related to the substrate holder.

The shielding electrode grid alone or together with the process chamber preferably closes or encloses the surface to be plasma treated and/or the substrate on at least five sides or surrounds it on at least five sides; In particular they enclose the surface to be plasma treated or the substrate substantially completely, i.e. substantially on all sides, or surround it substantially completely, i.e. on all sides. The shielding electrode grid is preferably connected to ground or a negative potential or is preferably configured to be connected to ground or a negative potential or to float in the operating state. The substrate holder is configured to hold the substrate in the Faraday cage formed. The shielding electrode grid, optionally together with the process chamber, delimits or delimit a volume around the substrate, preferably in all spatial directions. The Faraday cage thus preferably delimits a volume in which the substrate is provided. The shielding electrode grid can be designed in the form of a perforated plate (i.e., for example, with round gaps). This enables a particularly simple production of the shielding electrode grid. The shielding electrode grid can also be embodied, for example, by means of wires running parallel to one another (i.e., for example, vertical or horizontal wires). This enables a significantly increased grid transparency than a conventional grid.

The region of the shielding electrode grid opposite (i.e. facing) the surface to be plasma treated preferably has a distance d from the surface to be plasma treated that is less than or equal to 10 mean free paths for electron-neutral gas particle collisions. Preferably, d is greater than or equal to 0.1 mean free paths for electron-neutral gas particle collisions. The following preferably applies:

$$0.1 \cdot {λ}_{mfp} \leq d \leq 10 \cdot {λ}_{mfp}$$

λ_{mfp} is the mean free path for electron-neutral gas particle collisions in plasma. This is understood to mean the mean free path between two collisions of electrons and neutral gas particles. It is given by:

$${λ}_{mfp} = \frac{{k}_{B} T}{p \cdot {( σ )}_{ϕ}}$$

Here, k_{B} denotes the Boltzmann constant, T denotes the absolute temperature in Kelvin, p denotes the pressure in Pascal and (σ)_{φ} denotes the total effective cross-section for inelastic collisions between electrons and the precursor or working gas atoms or molecules. This cross section is to be used for electrons whose kinetic energy corresponds to the ionization energy φ of the working gas particles. The ionization energy is a constant that can be looked up in appropriate tables. The total effective cross-section depends on the working gas and must also be taken from the relevant literature. Examples of sources are:
Subramanian, K. P., and Vijay Kumar. “Total electron scattering cross sections for argon, krypton and xenon at low electron energies.” Journal of Physics B: Atomic and Molecular Physics (1968-1987) 20.20 (1987): 5505.
Straub, H. C., et al. “Absolute partial cross sections for electron-impact ionization of H 2, N 2, and O 2 from threshold to 1000 eV.” Physical Review A 54.3 (1996): 2146.
Itikawa, Yukikazu. “Cross sections for electron collisions with carbon monoxide.” Journal of Physical and Chemical Reference Data 44.1 (2015): 013105.
Itikawa, Yukikazu. “Cross sections for electron collisions with carbon dioxide.” Journal of Physical and Chemical Reference Data 31.3 (2002): 749-767.
Yanguas-Gil, Angel, José Cotrino, and Luís L. Alves. “An update of argon inelastic cross sections for plasma discharges.” Journal of Physics D: Applied Physics 38.10 (2005): 1588.
Stein, T. S., et al. “Measurements of total scattering cross sections for low-energy positrons and electrons colliding with helium and neon atoms.” Physical Review A 17.5 (1978): 1600.
   Subramanian, K. P., and Vijay Kumar. “Total electron scattering cross sections for argon, krypton and xenon at low electron energies.” Journal of Physics B: Atomic and Molecular Physics (1968-1987) 20.20 (1987): 5505.

### SUMMARY

The method preferably further includes one or more of the following steps: Deposition of ions from the plasma on the surface to be plasma treated, coating of the surface to be plasma treated with ions from the plasma, nitriding of the surface to be plasma treated, plasma etching of the surface to be plasma treated, ion implantation into the surface to be plasma treated and/or enrichment of dopants in the surface to be plasma treated, surface modification and cleaning. The present method makes this possible in particular on small structured three-dimensional substrates as well as on large areas with preferably high growth or enrichment rates. The voltage source is configured, in particular, to apply a voltage to the substrate holder.

The shielding electrode grid preferably has a transparency of at least 20%, preferably at least 30%, even more preferably at least 50% or at least 80% or at least 90%. Preferably, a grid spacing of the shielding electrode grid is less than 3 times the debye length, preferably less than 2 times the debye length, particularly preferably less than 1.5 times the debye length (of the plasma to be provided). The plasma source may also be embodied as an ion source. The plasma source can be operated with AC, DC, laser radiation, pulsed or high-frequency. Preferably, the plasma is generated in such a way that the plasma density on the side of the shielding electrode grid facing away from the surface to be plasma treated is less than 1/10 of the plasma density between the shielding electrode grid and the surface to be plasma treated. The plasma source can be located outside or inside the space delimited by the shielding electrode grid and possibly the process chamber, in particular outside or inside the Faraday cage. The plasma source may be voltage, current, power and/or energy controlled (joule mode). The process preferably takes place at subatmospheric, atmospheric or superatmospheric pressure, for example in the range between 10⁻¹⁰ mbar to 500 bar. The process chamber is preferably a vacuum chamber. The shielding electrode grid is preferably electrically insulated from the process chamber, in particular if it alone forms the Faraday cage around the substrate.

Preferably, the method further comprises the step of: Generating a vacuum in the process chamber (in particular a vacuum chamber). The generation of a vacuum is understood to mean the generation of a negative pressure with respect to atmospheric pressure. A pressure in the process chamber of preferably less than 500 mbar, particularly preferably less than 100 mbar, even more preferably less than 10 mbar, less than 1 mbar or less than 10⁻¹ mbar, is generated. Preferably, a low vacuum with a pressure of between 1 and 1013 mbar, a fine vacuum with a pressure of between 10⁻³ and 1 mbar or a high vacuum with a pressure of between 10⁻⁸ and 10⁻³ mbar is provided. Alternatively, an overpressure can also be generated in the process chamber.

It is preferred if the shielding electrode grid substantially completely surrounds the surface to be plasma treated. Alternatively, it is preferred if the shielding electrode grid and a portion of the process chamber together substantially completely surround the surface to be plasma treated, wherein the shielding electrode grid is optionally electrically conductively connected to the process chamber. In particular, the Faraday cage may be formed by the shielding electrode grid alone or by the shielding electrode grid and the process chamber. The shielding electrode grid preferably encloses or surrounds a space extending normal to the surface to be plasma treated, at least in the direction normal to the surface to be plasma treated and in the directions perpendicular to the surface to be plasma treated.

It is preferred if the Faraday cage has an extension perpendicular to the surface of the substrate of between 0.01 and 50, preferably between 0.1 and 10, mean free paths of the paths for electron-neutral gas particle collisions in the plasma. It is preferred if a normal distance of a region of the shielding electrode grid from the surface of the substrate to be plasma treated is between 0.1 and 10 mean free paths for electron-neutral gas particle collisions. It is advantageous if the region of the shielding electrode grid opposite the surface to be plasma treated extends at a distance of at least 0.1, preferably at least 0.2, particularly preferably at least 1, mean free paths for electron-neutral gas particle collisions in the plasma from the surface to be plasma treated.

It is preferred if the method further comprises the step of: Introducing a gaseous precursor into the process chamber. The gaseous precursor preferably comprises oxygen, nitrogen, hydrogen, nitrogen oxides, carbon monoxide, carbon dioxide and/or hydrocarbons.

It is preferred if the method further comprises the step of: Introducing a noble gas into the process chamber. The noble gas is preferably argon or helium or a noble gas mixture.

It is preferred if the method further comprises the step of: Sublimation of a solid in the process chamber. This can be done, for example, by sputtering, arc evaporation or other PVD processes (PVD=physical vapour deposition).

Preferably, a voltage of more than +1 volt or less than-1 volt is applied to the substrate. A voltage of preferably more than +10 volts or less than-10 volts, even more preferably a voltage of more than +100 volts or less than-100 volts, is applied to the substrate.

It is preferred if the shielding electrode grid is electrically insulated from the substrate. This ensures that the shielding electrode grid is connected to ground or another potential against which the substrate is biased.

Preferably, the method and the device for providing a plasma for plasma treatment of a surface of a substrate are used in a method for plasma assisted vapour deposition, in particular in a method for plasma enhanced chemical vapour deposition (PECVD). Advantageously, the method or the device for providing a plasma for plasma treatment of the surface of the substrate is used in a method for deposition on the surface, for coating or activating the surface, for nitriding, for plasma etching, for ion implantation (e.g. plasma immersion ion implantation) and/or for enriching dopants in the substrate. Preferably, methods and the device for providing a plasma for plasma treatment of a surface of a substrate are used for deposition on the substrate, coating the substrate, for nitriding, for plasma etching, for ion implantation (e.g. PIII) and/or for enriching dopants in the substrate.

With reference to the device according to the invention, it is advantageous if the device has a vacuum pump for generating a vacuum in the process chamber. The vacuum pump is preferably configured to generate a pressure in the process chamber of preferably less than 500 mbar, particularly preferably less than 100 mbar, even more preferably less than 10 mbar, less than 1 mbar or less than 10⁻¹ mbar.

It is preferred if the shielding electrode grid has an insulating element for electrically insulating the shielding electrode grid from a substrate held by the substrate holder. In particular, the shielding electrode grid has an insulating element for electrically insulating the shielding electrode grid from the substrate holder.

It is preferred if the shielding electrode grid comprises metal (or another conductive material). Preferably, the shielding electrode grid is made of metal (or another conductive material). Advantageously, in the present invention, the shielding electrode grid need not be made of the material of which the substrate itself is made.

It is preferred if the plasma source is provided within a space substantially delimited by the shielding electrode grid and adjacent to the surface to be treated. Advantageously, the plasma is then produced only within this space due to the shielding effect. The plasma source is particularly preferably provided within the Faraday cage.

Alternatively, the plasma source is provided outside a space substantially delimited by the shielding electrode grid and adjacent to the surface to be plasma treated. In particular, it is advantageous if the plasma source is provided outside the Faraday cage. In this case, a plasma with a relatively low plasma density may occur outside the Faraday cage between the shielding electrode grid and the plasma source, advantageously the plasma is concentrated inside the Faraday cage.

It is preferred if the shielding electrode grid substantially completely surrounds the surface to be plasma treated. Alternatively, it is preferred if the shielding electrode grid and a portion of the process chamber together substantially completely surround the surface to be plasma treated, wherein the shielding electrode grid is optionally electrically conductively connected to the process chamber.

### BRIEF DESCRIPTION OF THE DRAWINGS

In the following, the invention will be explained in more detail with reference to particularly preferred embodiments illustrated in the figures, to which, however, the invention shall not be limited.

FIG. 1 shows a first preferred embodiment of a device for providing a plasma for plasma treatment of a surface of a substrate.

FIG. 2 shows a second preferred embodiment of the device for providing a plasma for plasma treatment of a surface of a substrate.

FIG. 3 shows a third preferred embodiment of a device for providing a plasma for plasma treatment of a surface of a substrate.

FIG. 4 shows a fourth preferred embodiment of the device for providing a plasma for plasma treatment of a surface of a substrate.

### DETAILED DESCRIPTION OF THE INVENTION

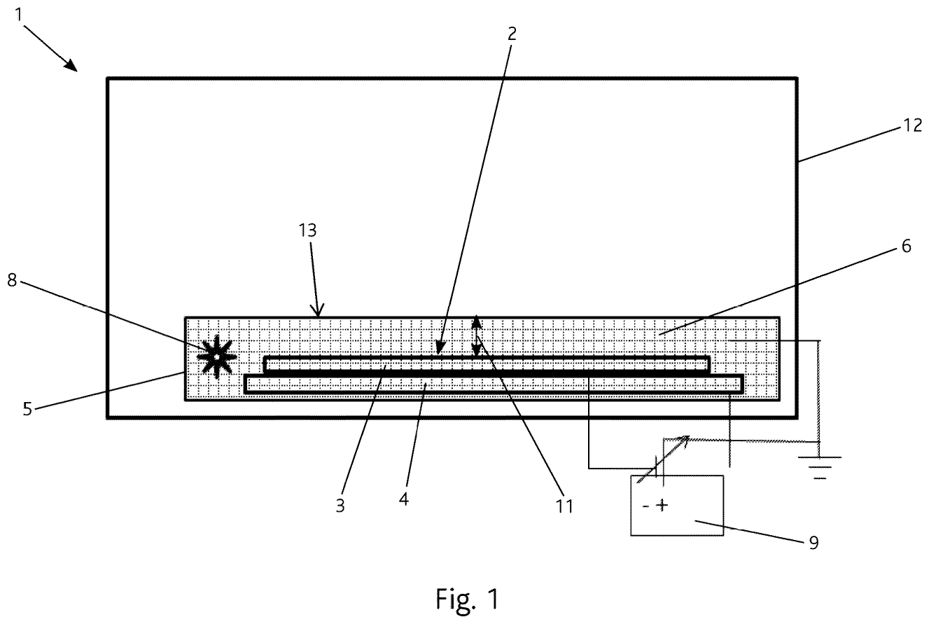

FIG. 1 shows a first preferred embodiment of a device 1 for providing a plasma for plasma treatment of a surface 2 of a substrate 3. The device 1 has a process chamber 12. A substrate holder 4 for holding the substrate 3 and a shielding electrode grid 5 are provided in the process chamber 12. The shielding electrode grid 5 is electrically conductive. The shielding electrode grid may be grounded, as shown in the figure, or may have a different potential. A region 13 of the shielding electrode grid 5 extends at a distance from and along the surface 2 to be plasma treated, such that the shielding electrode grid 5 substantially covers the surface to be plasma treated. The region 13 of the shielding electrode grid 5 opposite the surface 2 to be plasma treated extends at a distance 11 of less than or equal to 20 cm from the surface 2 to be plasma treated or at a distance 11 of less than or equal to 10 mean free paths for electron-neutral gas particle collisions in the plasma from the surface 2 to be plasma treated during operation of the device 1. In this embodiment, the shielding electrode grid not only surrounds a space adjacent to the surface 2 to be plasma treated in the direction normal to the surface 2 to be plasma treated and in the directions parallel to the surface 2 to be plasma treated, but substantially completely surrounds the surface 2 to be plasma treated in this embodiment and thus forms a Faraday cage 6 around the substrate. In particular, the shielding electrode grid 5 has a normal distance from the surface 2 of the substrate 3 to be plasma treated of less than 20 cm. Thus, a narrowly limited volume is formed adjacent to the surface 2, in which the plasma is concentrated and thus a high plasma density for plasma treatment of the surface 2 is achieved. In the volume delimited by the shielding electrode grid 5, in particular in the Faraday cage 6, a plasma source 8 is provided for providing a vacuum in the process chamber 12, in particular in the Faraday cage 6. In addition, a voltage source 9 is provided for applying a voltage to a substrate 3 held by the substrate holder 4.

In order to electrically insulate the shielding electrode grid 5 from the substrate 3, an insulating element may be provided. The shielding electrode grid preferably comprises metal or another conductive material.

In operation, the substrate 3 is attached to the substrate holder 4. A vacuum is created in the process chamber. In particular, gaseous precursors and a noble gas or noble gas mixture are introduced into a process chamber or solids are sublimated in the process chamber. Plasma source 8 generates a plasma. Voltage source 9 applies a voltage to substrate 3.

The Faraday cage 6 preferably has an extension perpendicular to the surface 2 of the substrate 3 to be plasma treated of preferably between 0.1 and 10 mean free paths for electron-neutral gas particle collisions in the plasma.

Advantageously, the plasma is limited to a narrow space by the shielding electrode grid 5 or the Faraday cage represented by the shielding electrode grid 5, and a spatially narrow, homogeneous plasma with a high plasma density is formed, which in turn enables high growth or etching rates of the layers to be applied/removed or rapid doping rates. Due to the narrow spatial limitation of the plasma, a considerable part of the process energy to be introduced is also saved, which increases energy efficiency.

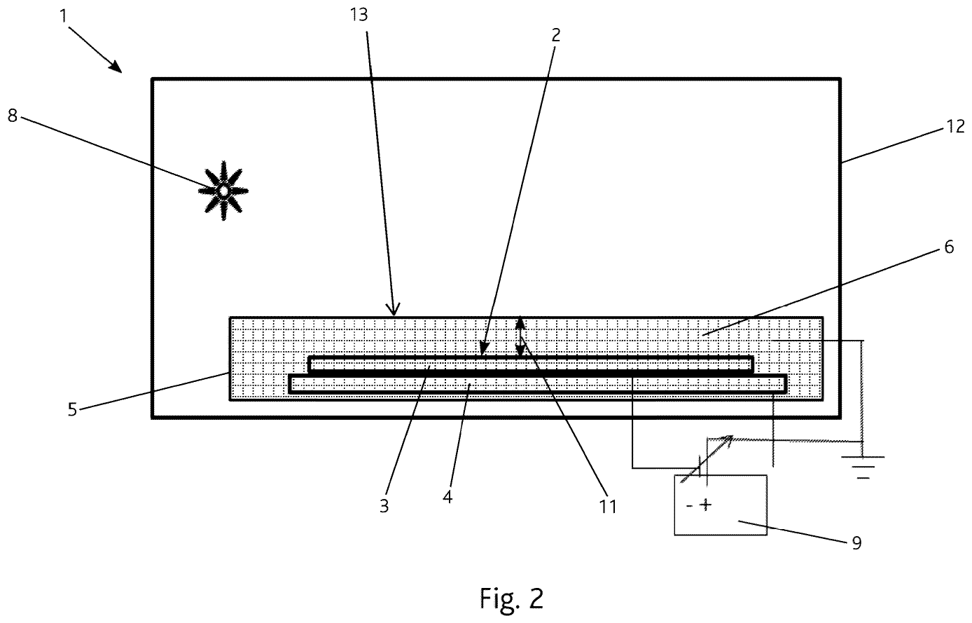

FIG. 2 shows a second preferred embodiment of the device 1 for providing a plasma for plasma treatment of a surface 2 of a substrate 3. This differs from the first embodiment only in that the plasma source 8 is provided outside the space delimited by the shielding electrode grid 5 and adjacent to the surface 2 to be plasma treated, in particular outside the Faraday cage 6. In this exemplary embodiment, although there is a low plasma density outside the Faraday cage 6, a high plasma density is nevertheless achieved inside the Faraday cage 6.

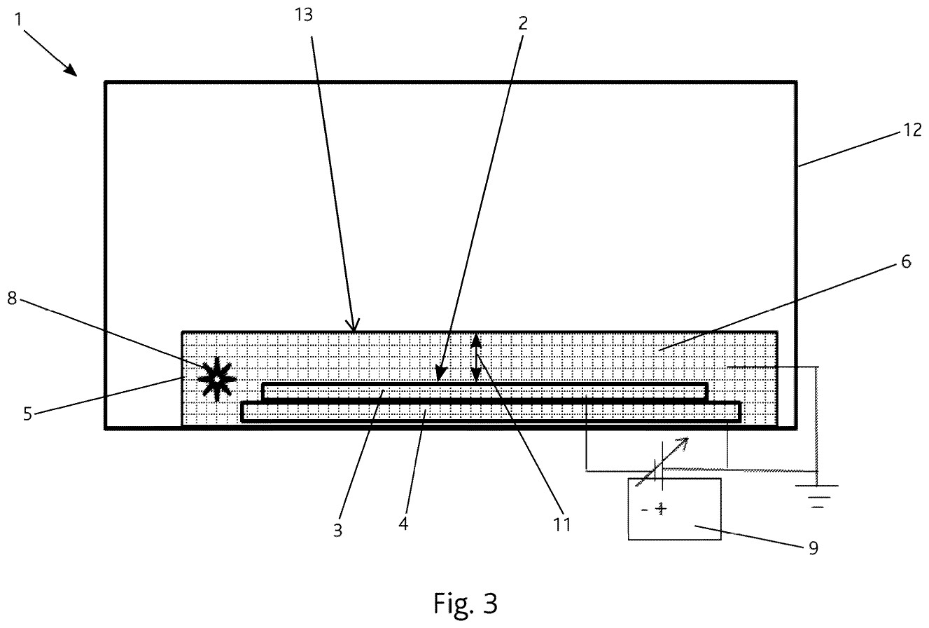

FIG. 3 shows a third preferred embodiment of the device 1 for providing a plasma for plasma treatment of a surface 2 of a substrate 3. This differs from the first embodiment only in that the shielding electrode grid 5 is electrically conductively connected to the process chamber 12 and in that the shielding electrode grid 5 and the process chamber 12 together substantially completely surround the substrate 3. Thus, in this embodiment, the shielding electrode grid 5 and a portion of the process chamber 12 together form the Faraday cage.

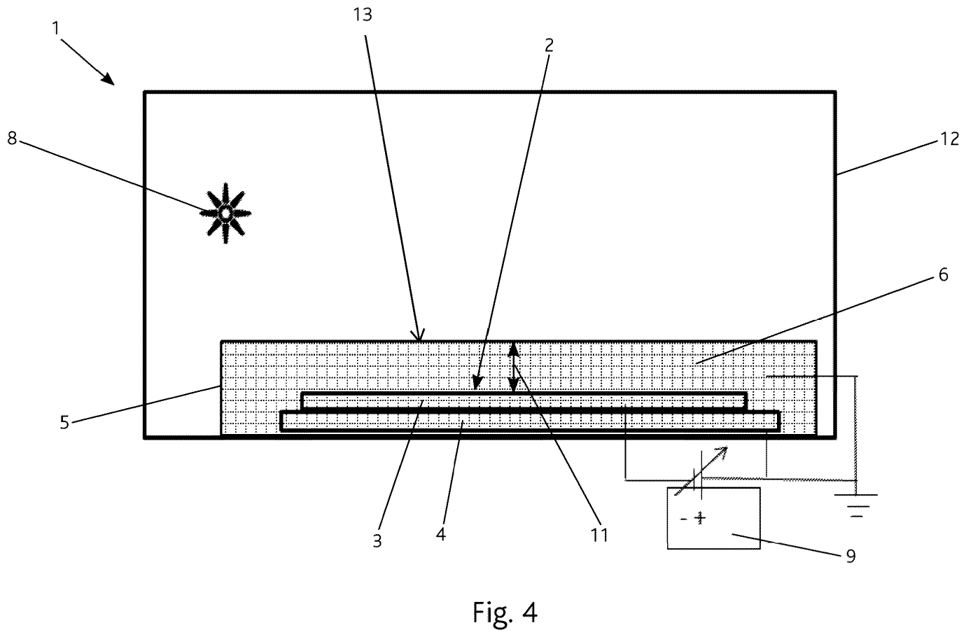

FIG. 4 shows a fourth preferred embodiment of the device 1 for providing a plasma for plasma treatment of a surface 2 of a substrate 3. This differs from the third embodiment only in that the plasma source 8 is provided outside the space delimited by the shielding electrode grid 5 and adjacent to the surface 2 to be plasma treated, in particular outside the Faraday cage 6.

1. A method for providing a plasma for plasma treatment of a surface of a substrate, the method comprising:
providing a process chamber;
providing a substrate in the process chamber;
providing a shielding electrode grid in the process chamber, wherein at least one region of the shielding electrode grid extends at a distance from and along the surface to be plasma treated, such that the shielding electrode grid substantially covers the surface to be plasma treated, wherein the shielding electrode grid is electrically conductive;
providing a plasma in the process chamber;
applying a voltage to the substrate;
wherein the region of the shielding electrode grid opposite the surface to be plasma treated extends at a distance of less than or equal to 10 mean free paths for electron-neutral gas particle collisions in the plasma from the surface to be plasma treated.

2. The method according to claim 1, wherein the shielding electrode grid substantially completely surrounds the surface to be plasma treated.

3. The method according to claim 1, wherein the shielding electrode grid and a portion of the process chamber together substantially completely surround the surface to be plasma treated.

4. The method according to claim 1, wherein the shielding electrode grid encloses a space extending normal to the surface to be plasma treated at least in a direction normal to the surface to be plasma treated and in directions perpendicular to the surface to be plasma treated.

5. The method according to claim 1, further comprising the step of:
generating a vacuum in the process chamber.

6. The method according to claim 1, wherein the region of the shielding electrode grid opposite the surface to be plasma treated extends at a distance of at least 0.1 mean free paths for electron-neutral gas particle collisions in the plasma from the surface to be plasma treated.

7. The method according to claim 1, further comprising the step of:
introducing a gaseous precursor into the process chamber.

8. The method according to claim 1, further comprising the step of:
introducing a noble gas into the process chamber.

9. The method according to claim 1, further comprising the step of:
sublimation of a solid in the process chamber.

10. The method according to claim 1, wherein a voltage of more than +1 volt or less than −1 volt is applied to the substrate.

11. The method according to claim 1, wherein the shielding electrode grid is electrically insulated from the substrate.

12. A method for plasma assisted vapour deposition, wherein the plasma is provided according to claim 1.

13. A device for providing a plasma for plasma treatment of a surface of a substrate, comprising:
a process chamber;
a substrate holder for holding the substrate in the process chamber;
a shielding electrode grid in the process chamber, wherein at least one region of the shielding electrode grid extends at a distance from and along a surface to be plasma treated, such that the shielding electrode grid substantially covers the surface to be plasma treated, wherein the shielding electrode grid is electrically conductive;
a plasma source for providing a plasma in the process chamber;
a voltage source for applying a voltage to a substrate held by the substrate holder;
wherein the region of the shielding electrode grid opposite the surface to be plasma treated extends at a distance of less than or equal to 20 cm from the surface to be plasma treated.

14. The device according to claim 13, comprising a vacuum pump for generating a vacuum in the process chamber.

15. The device according to claim 13, wherein the shielding electrode grid has an insulating element for electrically insulating the shielding electrode grid from a substrate held by the substrate holder.

16. The device according to claim 13, wherein the shielding electrode grid comprises metal.

17. The device according to claim 13, wherein the plasma source is provided within a space substantially delimited by the shielding electrode grid and adjacent to the surface to be plasma treated.

18. The device according to claim 13, wherein the plasma source is provided outside a space substantially delimited by the shielding electrode grid and adjacent to the surface to be plasma treated.

19. The device according to claim 13, wherein the shielding electrode grid substantially completely surrounds the surface to be plasma treated.

20. The device according to claim 13, wherein the shielding electrode grid and a portion of the process chamber together substantially completely surround the surface to be plasma treated.

21. The method according to claim 1, wherein the shielding electrode grid and a portion of the process chamber together substantially completely surround the surface to be plasma treated, wherein the shielding electrode grid is electrically conductively connected to the process chamber.

22. A method for plasma enhanced chemical vapour deposition, wherein the plasma is provided according to claim 1.

23. The device according to claim 13, wherein the shielding electrode grid and a portion of the process chamber together substantially completely surround the surface to be plasma treated, wherein the shielding electrode grid is electrically conductively connected to the process chamber.
